(19) United States
(12) Patent Application Publication
(10) Pub. No.: US 2006/0231960 A1
(43) Pub. Date: Oct. 19, 2006

(54) Non-cavity semiconductor packages

(75) Inventors: Chao-Yuan Su, Kaohsiung (TW); Pei-Haw Tsao, Taichung City (TW); Chender Huang, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/107,030

(22) Filed: Apr. 15, 2005

(51) Int. Cl. H01L 23/28

(52) U.S. Cl. 257/787

(57) ABSTRACT

Non-cavity semiconductor packages. One embodiment of the packages includes a non-cavity substrate, a first die, an encapsulant, and a second die. The non-cavity substrate comprises a first surface and an opposite second surface. The first surface comprises an external terminal thereon. The first die is attached and wire-bonded to the first surface of the substrate. The encapsulant covers the first die. The second die electrically connects to the second surface of the substrate. The second die is larger than the first die.

### BACKGROUND

The invention relates to semiconductor technology, and more specifically to a multi-chip module (MCM).

FIG. 1 shows a conventional stacked-die package. The package comprises a substrate 100 comprising first and second surfaces 101 and 102. Solder balls 150 are disposed on the first surface 101. Solder bumps 112 electrically connect the second surface 102 of the substrate 100 and an active surface of a large die 110, i.e. a digital device. A small die 120, i.e. an analog device, is stacked on a back surface of the large die 110. The small die 120 is wire-bonded to the substrate via wires 131 and 132.

Unfortunately, die area difference between the large die 110 and small die 120 may induce a quality issue. As shown in FIG. 1, the long wire 132 potentially contacts an edge of the large die 110, and/or shifts and contacts the neighboring wires (not shown) during a molding process to form an encapsulant 140, inducing a wire-short problem negatively affecting the process yield. Further, the stacked-die package is typically between 1.4 and 1.6 mm high, and cannot be reduced.

Typically, bond pad arrangement of the small die 120 is modified to avoid the wire-short problem. In a modified die 120, bond pads are arranged only on two sides of the active surface. The modified die 120 is attached to an area near an edge of the back surface of the large die 110, and thus the needed bonding wire length is decreased to avoid the wire-short problem. The needed die area of the modified small die, however, must be increased, increasing fabrication cost thereof.

Yang discloses an MCM in U.S. Pat. No. 6,620,648. The MCM includes first and second chips, and a laminate layer sandwiched therebetween. The laminate layer includes upper and lower sides, and central passage. The first chip is adhered to the lower side of the laminate layer using an adhesive layer, and electrically connected to the upper side of the laminate layer by a bonding wire through the central passage. The second chip is electrically connected to the upper side of the laminate layer by a bump therebetween disposed beyond the central passage. The MCM has a relatively low profile, but the potential wire-short problem cannot be avoided. The wire, through the central passage and connecting to a pad on the upper side of the laminate layer, potentially contacts the second chip to be short thereto.

Cheng et al. disclose an MCM including a chip embedded in a substrate thereof in U.S. Pat. No. 6,506,633, reducing the MCM profile and decrease the wire-short problem. The fabrication process for the substrate simultaneously packages the embedded chip. The good embedded chip is potentially scrapped when the process fails a substrate, resulting in a potential yield loss factor.

### SUMMARY

Thus, embodiments of the invention provide non-cavity semiconductor packages and methods for fabricating the same, reducing package profile and preventing wire-short problem without cost increase or inducement of other yield loss factor, thereby improving process yield and shrinking the profile of an end product utilizing the package.

Embodiments of the invention provide a non-cavity semiconductor package. The package comprises a non-cavity substrate, a first die, an encapsulant, and a second die. The non-cavity substrate comprises a first surface and an opposite second surface. The first surface comprises an external terminal thereon. The first die is attached and wire-bonded to the first surface of the substrate. The encapsulant covers the first die. The second die electrically connects to the second surface of the substrate. The second die is larger than the first die.

Embodiments of the invention further provide a non-cavity semiconductor package. The package comprises a non-cavity substrate, a first die, an encapsulant, a conductive bump, a second die, and an underfill. The non-cavity substrate comprises a first surface and an opposite second surface. The first surface comprises an external terminal thereon. The first die is attached and wire-bonded to the first surface of the substrate. The encapsulant covers the first die. The conductive bump protrudes from and electrically connects to the second surface of the substrate. The second die is larger than the first die, and comprises an active surface electrically connecting to the conductive bump. The underfill is disposed between the second die and the second surface of the substrate, and encapsulates the conductive bump.

Embodiments of the invention further provide a non-cavity semiconductor package. The package comprises a non-cavity substrate, a first die, a first encapsulant, a conductive bump, a second die, an underfill, and a second encapsulant. The non-cavity substrate comprises a first surface and an opposite second surface. The first surface comprises an external terminal thereon. The first die is attached and wire-bonded to the first surface of the substrate. The first encapsulant covers the first die. The conductive bump protrudes from and electrically connects to the second surface of the substrate. The second die is larger than the first die, and comprises an active surface electrically connecting to the conductive bump. The underfill is disposed between the second die and the second surface of the substrate, and encapsulates the conductive bump. The second encapsulant covers the second die and underfill.

Embodiments of the invention further provide a method for fabricating a non-cavity semiconductor package. First, a non-cavity substrate, comprising a first surface and an opposite second surface, is provided. The first surface comprises an external terminal thereon. A first die is then attached and wire-bonded to the first surface of the substrate. Next, an encapsulant is formed, covering the first die. Further, a second die, larger than the first die, is attached and electrically connected to the second surface of the substrate via a conductive bump electrically connecting therebetween utilizing flip chip technology. Finally, an underfill is disposed between the second die and the second surface of the substrate, encapsulating the conductive bump.

Embodiments of the invention further provide a method for fabricating a non-cavity semiconductor package. First, a non-cavity substrate, comprising a first surface and an opposite second surface, is provided. The first surface comprises an external terminal thereon. A second die is then attached and electrically connected to the second surface of the substrate via a conductive bump electrically connecting therebetween utilizing flip chip technology. Next, an underfill is disposed between the second die and the second surface of the substrate, encapsulating the conductive bump. Next, a second encapsulant is formed, covering the second die and underfill. Further, a first die, smaller than the second die, is attached and wire-bonded to the first surface of the substrate. Finally, a first encapsulant is formed, covering the first die.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention can be more fully understood by reading the subsequent detailed description in conjunction with the examples and references made to the accompanying drawings, which are given by way of illustration only, and thus are not limitative of the invention, and wherein:

FIG. 1 is a cross-section of a conventional MCM.

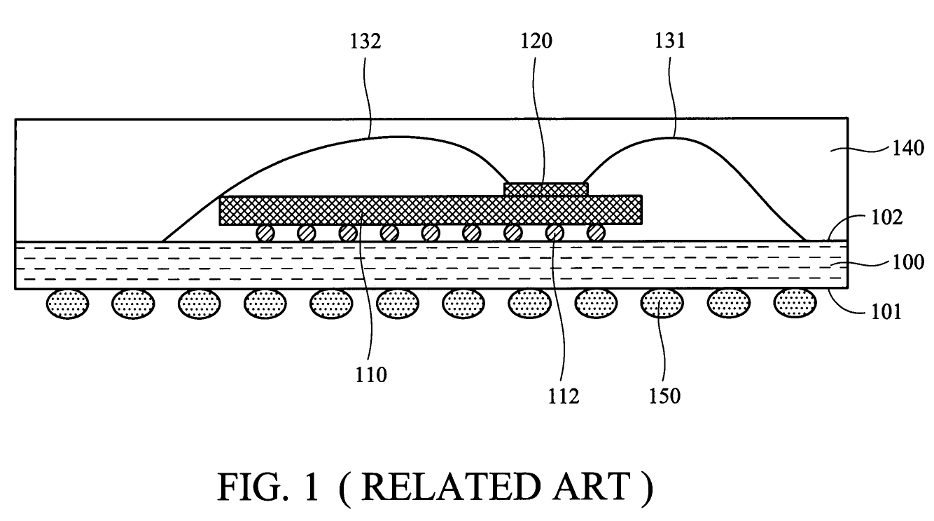

FIG. 2 is a cross-section of a non-cavity semiconductor package of one embodiment of the invention.

FIG. 3 is a cross-section of a non-cavity semiconductor package of an alternative embodiment of the invention.

FIG. 4 is a cross-section of a non-cavity semiconductor package of an alternative embodiment of the invention.

FIG. 5 is a top view of a die utilized in embodiments of the invention.

### DESCRIPTION

The following embodiments are intended to illustrate the invention more fully without limiting the scope of the claims, since numerous modifications and variations will be apparent to those skilled in this art.

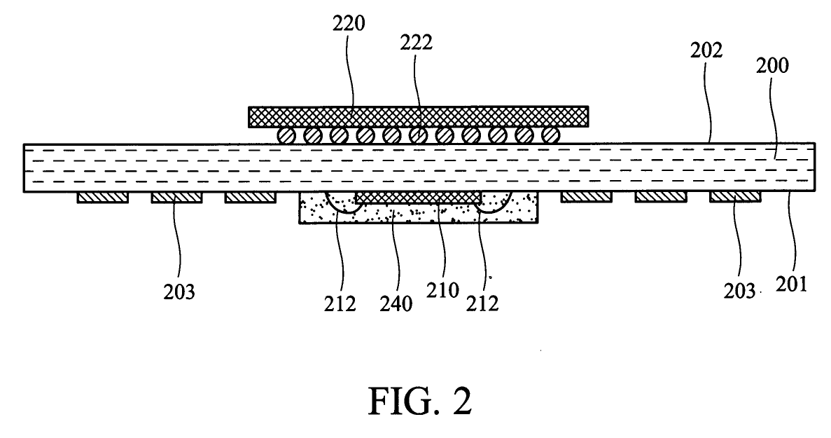

FIG. 2 shows a non-cavity semiconductor package of one embodiment of the invention. The package comprises a non-cavity substrate 200, a first die 210, an encapsulant 240, and a second die 220.

The non-cavity substrate 200, as the name indicates, has no cavity, and thus, the -substrate 200 can be a matrix substrate comprising a plurality of packaging units, simultaneously processed to increase throughput. One of the packaging units of the substrate 200 is shown in FIG. 2. The substrate 200 comprises a first surface 201 and an opposite surface 202. The first surface 203 comprises an external terminal 203 for connection to an external device such as a printed circuit board (PCB) for an electronic apparatus. The substrate 200 can be a leadframe, PCB, or other known package substrate. In this embodiment, the substrate 200 is a PCB. In some embodiments, the substrate 200 comprises two or more layers of wiring. In some embodiments, the substrate 200 is as thick as 0.20 mm or greater. In a preferred embodiment, the substrate 200 is approximately 0.26 mm thick.

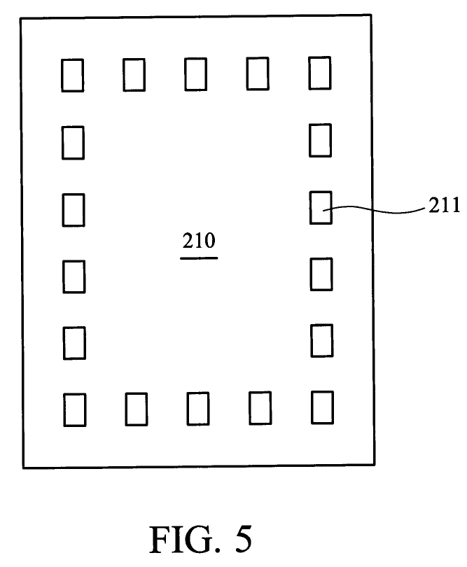

The first die 210 is attached and wire-bonded to the first surface 201 of the substrate 200. A wire 212 electrically connects the first die 210 to the first surface 201 of the substrate 200. An embodiment of a rectangular active surface of the first die 210 is shown in FIG. 5. Wire bonding pads 211 on the active surface of the die 210 can be arranged on four sides. The needed die area of the die 210 is reduced, and thus, fabrication cost thereof is decreased.

An encapsulant 240, such as a mixture of thermosetting epoxy and silica fillers, covers the die 210 and wire 212 to protect them from damage induced by environmental factors.

A second die 220, typically larger than the first die 210, is electrically connected to the second surface. 202 of the substrate 200. Alternatively, the second die 220 may be smaller than the first die 210. In some embodiments, a ratio of die area of the second die 220 to the first die 210 is as large as 2 or greater. In some specific embodiments, the ratio is between 2 and 4.

The second die 220 is preferably connected to the substrate 200 by flip chip technology to reduce the package profile. As shown in FIG. 2, for example, a conductive bump 222 protrudes from and electrically connects to the second surface 202 of the substrate 200, and the second die 220 electrically connects thereto. The conductive bump can be solder, gold, copper, conductive organic materials, or other conductive materials. In other embodiments, wire-bonding, tape-automatic bonding (TAB), or other known package technologies may be utilized to electrically connect the second die 220 and substrate 220. The substrate 200 is preferably sandwiched between the dice 220 and 210 to reduce footprint of the package.

In some embodiments, the die 220 may be replaced by a passive component, a connector, or a packaged IC. In some embodiments, a heat sink (not shown) may be thermally connected to the die 220 to assist heat dissipation.

It is appreciated that, since the die 210 is attached to the first surface 201 and the die 220 is attached to the second surface, long wire is not required and the die area difference therebetween no longer induces the wire-short problem. Further, neither cost increase, nor yield loss is potentially induced.

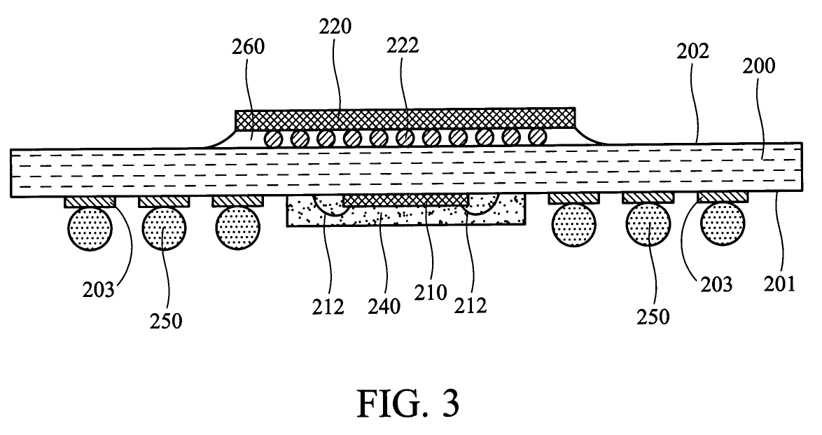

In an alternative embodiment, as shown in FIG. 3, an underfill 260 is disposed between the second die 220 and the second surface 202 of the substrate 200. The thermal expansion coefficient of the underfill 260 is between those of the die 220 and substrate 200 to be a buffer under exertion of thermal stress potentially induced by some environmental factors such as thermal cycles. The underfill 260 further encapsulates the conductive bump 222.

In some embodiments, the package comprises a solder ball 250 on the terminal 203. The solder ball can be lead-containing or lead-free as desired. The encapsulant 212 is preferably as thick as the solder ball 250 or less. In a preferred embodiment, the solder ball 250 is as high as approximately 0.4 mm and the encapsulant 240 is less than 0.3 mm thick.

In some embodiments, the package is as thick as 1.0 mm or less. In a preferred embodiment, the second die 220 is approximately 0.2 mm thick, a solder bump 220 electrically connecting between the second die 220 and the substrate 200 is approximately 0.07 mm high, the substrate 200 is approximately 0.26 mm thick, the solder ball 250 is as high as approximately 0.4 mm, and thus, the package is as thick as approximately 0.93 mm.

Details regarding other elements of the package are the same as the described, and thus, are omitted herefrom.

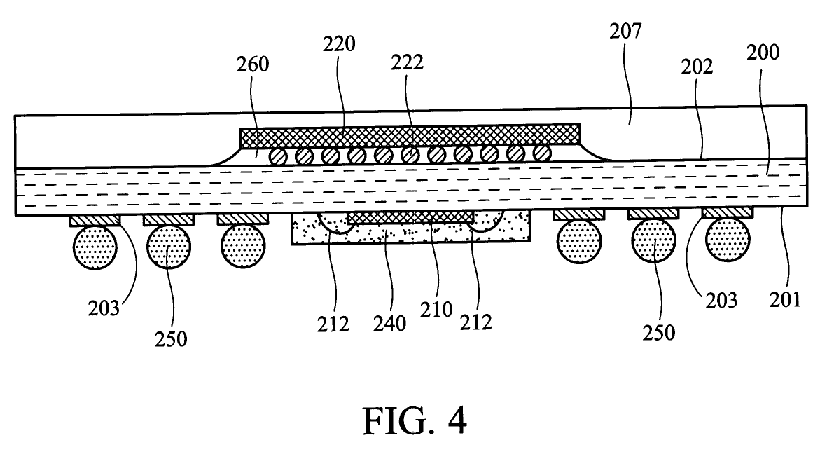

In an alternative embodiment, as shown in FIG. 4, an encapsulant 270 is formed, covering the second die 220. The encapsulant 270 may further protect the second die 220 from damage induced by environmental factors such as collision. Formation of the encapsulant 270 may slightly increase the package profile. In some embodiments, the package is as thick as approximately 1.1 mm or less. Details regarding other elements of the package are the same as described, and thus, are omitted herefrom.

Thus, the results show the efficacy of the inventive non-cavity semiconductor package in reducing package profile and preventing wire-short problem without cost increase and inducement of other yield loss factor, thus improving process yield and shrinking the profile of an end product utilizing the package.

Further, an embodiment of a method for forming the non-cavity semiconductor package in FIG. 3, for example, is provided. First, a non-cavity substrate 200, comprising a first surface 201 and an opposite second surface 202, is provided. The first surface 201 comprises an external terminal 203 thereon. A first die 210 is then attached and wire-bonded to the first surface 201 of the substrate 200. In some embodiments, a conductive or insulating thermosetting adhesive (not shown) is applied to a predetermined attachment area on the first surface 201, followed by attachment of the first die 210 to the adhesive and curing of the adhesive. In some embodiments, a wire 212, such as gold or aluminum, is utilized to electrically connect the first die 201 to the first surface 201 of the substrate 200.

Next, an encapsulant 240 is formed, covering the first die. In some embodiments, the encapsulant 240 is formed by dispensing a liquid compound (not shown) comprising a thermosetting epoxy and silica fillers, for example, to cover the first die 210, followed by hardening of the liquid compound to form the encapsulant 240. The wire 212 is typically covered by the encapsulant 240.

Further, a second die 220, larger than the first die 210, is attached and electrically connected to the second surface 202 of the substrate 200 via a conductive bump 222 electrically connecting therebetween utilizing flip chip technology. In some embodiments, the conductive bump 222 is previously formed on an active surface of the die 220, and then reflowed to form electrical connection between the second die 220 and the substrate 200 after attachment of the die 220 in upside down. In other embodiments, the conductive bump 222 is previously formed on a bump pad on the second surface 202 of the substrate 200 and then electrically connected to the second die 220 after attachment.

Finally, an underfill 260 is disposed between the second die 220 and the second surface 202 of the substrate 200 as a buffer to share thermal stress induced by the different thermal expansion coefficients between the second die 220 and the substrate 200. The underfill 260 encapsulates the conductive bump. Thus, the non-cavity semiconductor package shown in FIG. 3 is completed.

Further, an encapsulant 270 may be further formed covering the second die 220 to further provide protection therefor. In some embodiments, the encapsulant 270 is formed by a molding process. Thus, the non-cavity semiconductor package shown in FIG. 4 is completed.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed Is:

1. A non-cavity semiconductor package, comprising:
a non-cavity substrate comprising a first surface and an opposite second surface, the first surface comprising an external terminal thereon;
a first die attached and wire-bonded to the first surface of the substrate;
an encapsulant covering the first die; and
a second die, larger than the first die, electrically connecting to the second surface of the substrate.

2. The package as claimed in claim 1, wherein a ratio of die area of the second die to the first die is as large as 2 or greater.

3. The package as claimed in claim 1, wherein a ratio of die area of the second die to the first die is between 2 and 4.

4. The package as claimed in claim 1, wherein the substrate is a matrix substrate comprising a plurality of packaging units.

5. The package as claimed in claim 1, wherein the substrate is sandwiched between the first and second dice.

6. The package as claimed in claim 1, wherein the first die comprises a rectangular active surface comprising a plurality of wire-bonding pads arranged on four sides thereof.

7. A non-cavity semiconductor package, comprising:
a non-cavity substrate comprising a first surface and an opposite second surface, the first surface comprising an external terminal thereon;
a first die attached and wire-bonded to the first surface of the substrate;
an encapsulant covering the first die;
a conductive bump protruding from and electrically connecting to the second surface of the substrate;
a second die, larger than the first die, comprising an active surface electrically connecting to the conductive bump; and
an underfill disposed between the second die and the second surface of the substrate, encapsulating the conductive bump.

8. The package as claimed in claim 7, wherein a ratio of die area of the second die to the first die is as large as 2 or greater.

9. The package as claimed in claim 7, wherein a ratio of die area of the second die to the first die is between 2 and 4.

10. The package as claimed in claim 7, wherein the substrate is a matrix substrate comprising a plurality of packaging units.

11. The package as claimed in claim 7, wherein the substrate is sandwiched between the first and second dice.

12. The package as claimed in claim 7, further comprising a solder ball on the external terminal.

13. The device as claimed in claim 12, wherein the encapsulant is as thick as the solder ball or thinner.

14. The package as claimed in claim 7, wherein the first die comprises a rectangular active surface comprising a plurality of wire-bonding pads arranged on four sides thereof.

15. A non-cavity semiconductor package, comprising:
a non-cavity substrate comprising a first surface and an opposite second surface, the first surface comprising an external terminal thereon;
a first die attached and wire-bonded to the first surface of the substrate;
a first encapsulant covering the first die;
a conductive bump protruding from and electrically connecting to the second surface of the substrate;
a second die, larger than the first die, comprising an active surface electrically connecting to the conductive bump;
an underfill disposed between the second die and the second surface of the substrate, encapsulating the conductive bump; and
a second encapsulant covering the second die and underfill.

16. The package as claimed in claim 15, wherein a ratio of die area of the second die to the first die is as large as 2 or greater.

17. The package as claimed in claim 15, wherein a ratio of die area of the second die to the first die is between 2 and 4.

18. The package as claimed in claim 15, wherein the substrate is a matrix substrate comprises a plurality of packaging units.

19. The package as claimed in claim 15, wherein the substrate is sandwiched between the first and second dice.

20. The package as claimed in claim 15, further comprising a solder ball on the external terminal.

21. The device as claimed in claim 20, wherein the first encapsulant is as thick as the solder ball or thinner.

22. The package as claimed in claim 15, wherein the first die comprises a rectangular active surface comprising a plurality of wire-bonding pads arranged on four sides thereof.
